(19) United States
(12) Patent Application Publication
(10) Pub. No.: US 2009/0179248 A1
(43) Pub. Date: Jul. 16, 2009

(54) NAND FLASH MEMORY DEVICE AND METHOD OF FABRICATING THE SAME

(75) Inventors: Hee Sik Park, Chungcheongbuk-do (KR); Seong Jo Park, Chungcheongnam-do (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Gyeonggi-do (KR)

(21) Appl. No.: 12/401,420

(22) Filed: Mar. 10, 2009

Related U.S. Application Data
(63) Continuation of application No. 11/306,349, filed on Dec. 23, 2005.

(30) Foreign Application Priority Data
Jun. 30, 2005 (KR) 2005-57921

(51) Int. Cl. H01L 29/788

(52) U.S. Cl. 257/314; 257/E29.3

(57) ABSTRACT

A NAND flash memory device includes a semiconductor substrate having a drain select transistor; a source select transistor, and memory cell transistors connected in series between the drain select transistor and the source select transistor, and an oxide film formed in the semiconductor substrate at each of a first side and a second side of a gate of the source select transistor. A method of manufacturing a NAND flash memory device includes providing the semiconductor substrate and forming the oxide film in the semiconductor substrate at each of the first side and the second side of the gate of the source select transistor.

### RELATED APPLICATIONS

This is a continuation application which is based on and claims priority to U.S. patent application Ser. No. 11/306,349, entitled “NAND Flash Memory Device and Method of Fabricating the Same,” which was filed on Dec. 23, 2005, the entire disclosure of which is hereby incorporated by reference herein.

### BACKGROUND

Semiconductor memory devices can be mainly classified into RAM products, such as DRAM and SRAM, and ROM products. The RAM products are volatile, in which data are lost as time goes by, and are fast in the input and output speed of data. The ROM products can maintain its state once data are input, but are slow in the input and output speed of data.

There is an increasing demand for flash memory devices in which data can be electrically input and output, of these ROM products. The flash memory devices are devices that can be electrically erased at high speed while not removing it from a circuit board. The flash memory devices are advantageous in that the manufacturing cost per unit memory is cheap because a memory cell structure is simple and a refresh function for retaining data is not necessary.

The cell structure of the flash memory can be largely classified into a NOR type and a NAND type. The NOR type structure is disadvantageous in higher integration because it needs one contact per two cells, but is advantageous in higher speed because the cell current is high. The NAND type structure is disadvantageous in high speed because the cell current is low, but is advantageous in higher integration because a number of cells share one contact. Therefore, the NAND flash memory device has thus been in the spotlight as the next-generation memory devices for MP3 players, digital cameras and the like.

A cross-sectional and an equivalent circuit diagram of a general NAND flash cell array are shown in FIGS. 1 and 2, respectively.

Referring to FIGS. 1 and 2, in the NAND flash memory cell array, memory cell transistors MC1, . . . , MC16 each having a structure in which a floating gate 18 and a control gate 22 are stacked between a drain select transistor DST for selecting a unit string and a source select transistor SST for selecting the ground are connected in series to form one unit string.

The string is connected in plural in bit lines B/L1, B/L2, . . . in parallel to form one block. The blocks are symmetrically disposed around a bit line contact.

Transistors are arranged in matrix form of rows and columns. The gates of the drain select transistors DST and the source select transistors SST, which are arranged in the same columns, are connected to a drain select line DSL and a source select line SSL, respectively. Furthermore, the gates of the memory cells transistors MC1, . . . , MC16, which are arranged in the same columns, are connected to a number of corresponding word line W/L1, . . . , W/L16.

Furthermore, to the drain of the drain select transistor DST is connected the bit line B/L, and to the source of the source select transistor SST is connected a common source line CSL.

The memory cell transistors MC1, . . . , MC16 have a structure in which the floating gate 18 formed on a semiconductor substrate 10 with a tunnel oxide film 16 intervened therebetween, and the control gate 22 formed on the floating gate 18 with an interlayer dielectric film 20 intervened therebetween are stacked.

The floating gate 18 is formed over some of edges of an active region and a field region at both sides of the active region and is then isolated from the floating gate 18 of a neighboring cell transistor. The control gate 22 is connected to the control gate 22 of a neighboring cell transistor, including the floating gate 18 that is independently formed with the field region therebetween, thus forming the word line.

The select transistors DST, SST are transistors that do not use a floating gate for storing data, and connect the floating gate 18 and the control gate 22 through a butting contact on the field region within the cell array. Therefore, the select transistors DST, SST operate as MOS transistors electrically having one layer of a gate.

A program operation of the NAND flash memory device constructed above will now be described.

A voltage of 0V is applied to a bit line connected to a selected memory cell transistor, a power supply voltage (Vcc) is applied to a bit line connected to a non-selected memory cell transistor and a program voltage (Vpgm) is applied to a word line connected to a selected memory cell transistor. Electrons of the channel region are injected into the floating gate by way of Fowler-Nordheim (F-N) tunneling due to a high voltage difference between the channel region of the memory cell transistor and the control gate.

At this time, a pass voltage (Vpass) for transferring data (0V), which are applied to a selected bit line, to a selected memory cell transistor is applied to a word line connected to a non-selected memory cell transistor of a number of memory cell transistors located between a bit line and a ground node.

Meanwhile, to prevent program disturb given to the non-selected memory cell transistor connected to the selected word line and the non-selected bit line, the non-selected memory cell transistor has to be prevented from being programmed.

The non-selected memory cell transistor can be prevented from being programmed by boosting a channel voltage (Vch) of the non-selected memory cell transistor connected to the selected word line and the non-selected bit line.

FIG. 3 is a view showing the state of a unit string connected to a selected word line1 WL1 and a non-selected bit line. To prevent the non-selected memory cell transistor connected to the selected WL1 from being programmed, the channel voltage (Vch) of a corresponding unit string is boosted to a high level.

At this time, a strong electric field is formed in a junction overlap region of the source select transistor SST due to a difference between the voltage of 0V applied to the gate of the source select transistor SST and the voltage boosted to a high level. This electric field generates hot carriers.

Of the hot carriers, holes are moved toward the substrate under the influence of a substrate bias and electrons are moved into the unit string by means of the electric field.

Meanwhile, a strong vertical electric field is formed in the direction of the floating gate 18 due to the program voltage of 16 to 18V, which is applied to the gate of the non-selected memory cell transistor MC1 connected to the selected W/L1. The electrons moved into the unit string are injected into the floating gate 18 of the non-selected memory cell transistor MC1 under the influence of the vertical electric field. That is, program disturb is generated.

FIG. 4 is a graph showing a disturb characteristic of the source select transistor SST and the memory cell transistor MC1 adjacent to the source select transistor SST. FIG. 5 is a graph showing a disturb characteristic of the remaining memory cell transistors other than MC1.

From FIGS. 4 and 5, it can be seen that a disturb characteristic of MC1 becomes worse in comparison with other memory cells.

The disturb characteristic degradation phenomenon of the memory cell transistor MC1 adjacent to the source select transistor SST becomes more profound with devices becoming more fine. This limits characteristics and reliability of devices.

### SUMMARY

A method of manufacturing a NAND flash memory device includes providing a semiconductor substrate having a drain select transistor, a source select transistor, and memory cell transistors connected in series between the drain select transistor and the source select transistor, and forming an oxide film in the semiconductor substrate at each of a first side and a second side of a gate of the source select transistor.

A NAND flash memory device includes a semiconductor substrate having a drain select transistor, a source select transistor, and memory cell transistors connected in series between the drain select transistor and the source select transistor, and an oxide film formed in the semiconductor substrate at each of a first side and a second side of a gate of the source select transistor.

### BRIEF DESCRIPTION OF THE DRAWINGS

FIG. 1 is a cross-sectional view showing a vertical structure of a conventional NAND flash memory cell array;

FIG. 2 is an equivalent circuit diagram of the NAND flash cell array shown in FIG. 1;

FIG. 3 is a view showing the state of a string connected to a selected word line1 W/L1 and a non-selected bit line shown in FIGS. 1 and 2;

FIG. 4 is a graph showing a disturb characteristic of a source select transistor SST and a memory cell transistor MC1 adjacent to the source select transistor SST shown in FIGS. 1-3;

FIG. 5 is a graph showing a disturb characteristic of the remaining memory cell transistors other than MC1 shown in FIGS. 1-3; and

FIGS. 6A to 6C are cross-sectional views for illustrating an example of a method of fabricating a flash memory device.

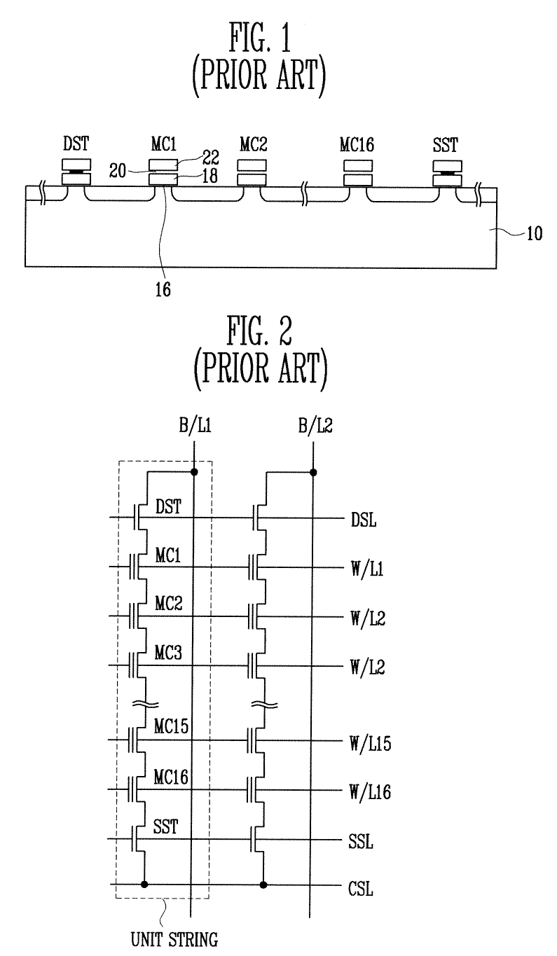

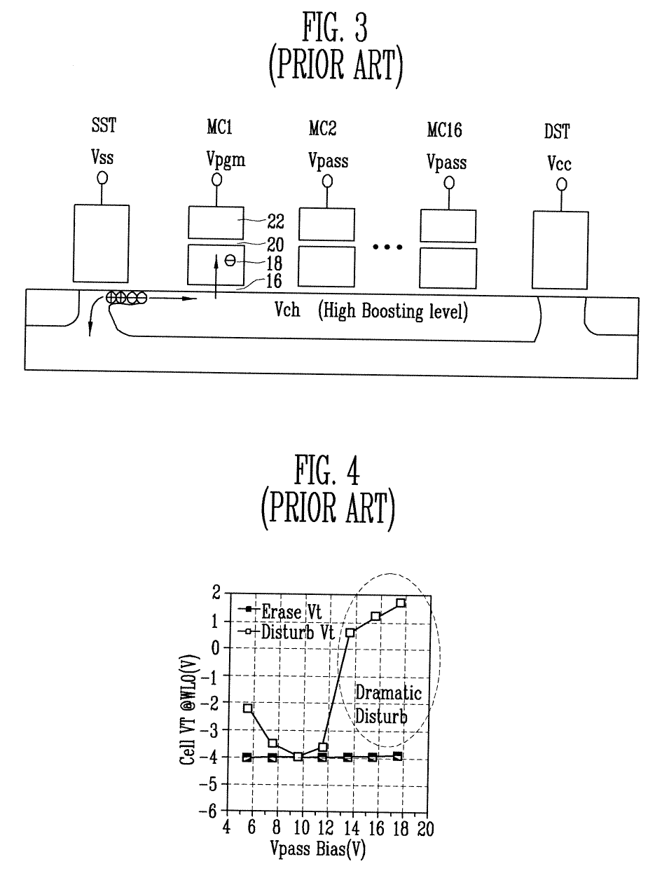

### DETAILED DESCRIPTION

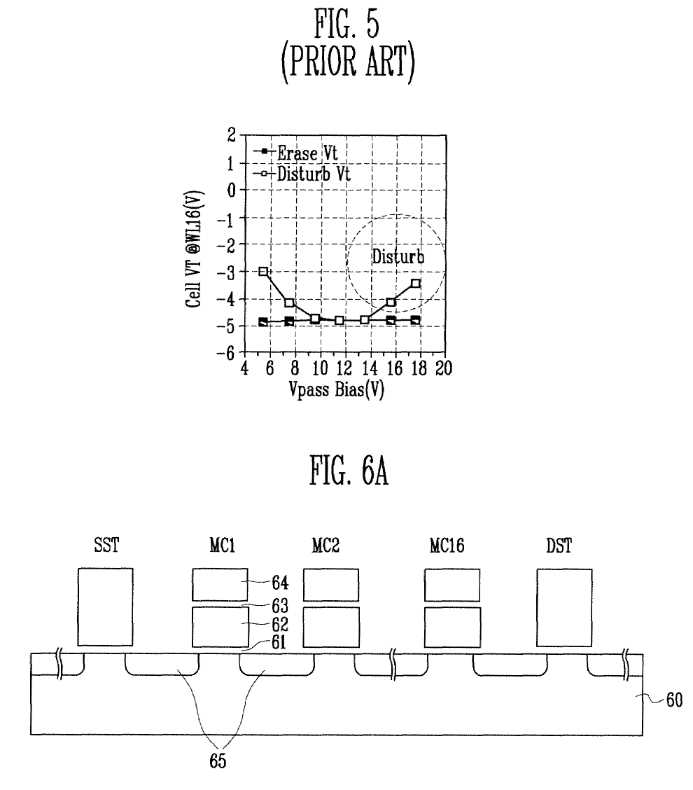

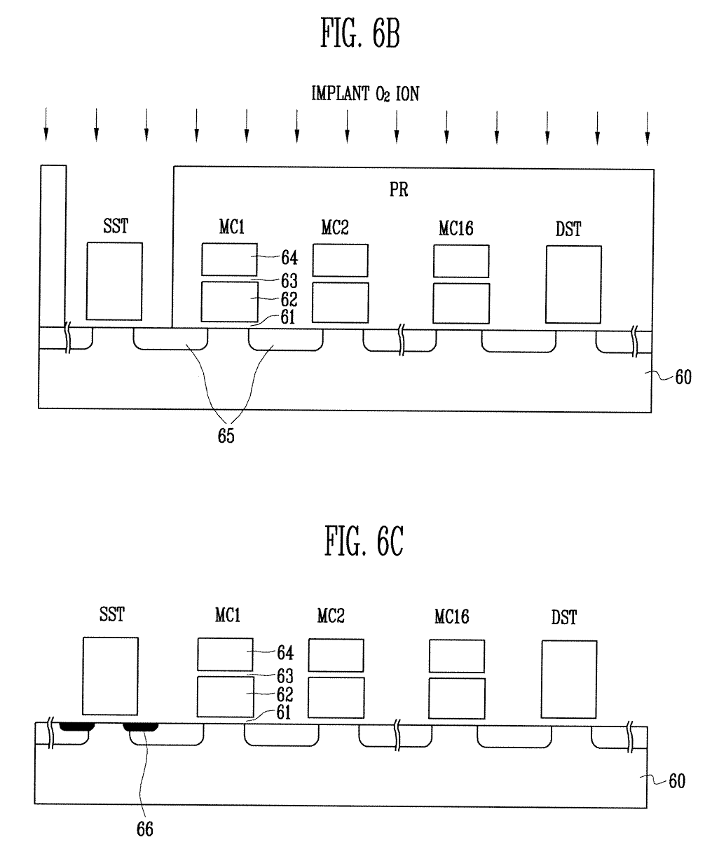

FIGS. 6A to 6C are cross-sectional views for illustrating an example of a method of fabricating a flash memory device.

As shown in FIG. 6C, the flash memory device includes memory cell transistors MC1, . . . , MC16, which are connected in series between a drain select transistor DST and a source select transistor SST in a semiconductor substrate 60, and oxide films 66 having a shallow depth, which are formed in the semiconductor substrate 60 at both sides of the gate 67 of the source select transistor SST. The depth of the oxide film 66 is shallower than that of source and drain junction 65 of the source select transistor SST.

To fabricate the flash memory device constructed above, the memory cell transistors MC1, . . . , MC16, which are connected in series between the drain select transistor DST and the source select transistor SST, are formed on and in the semiconductor substrate 60, as shown in FIG. 6A.

That is, a tunnel oxide film 61, a conductive film 62 for a floating gate and an interlayer dielectric film 63 are sequentially formed on the semiconductor substrate 60. A portion of the interlayer dielectric film 63, in which a drain select transistor and a source select transistor will be formed, is removed. A polysilicon film and a tungsten silicide film are then sequentially deposited on the entire surface to form a control gate film 64. The control gate film 64, the interlayer dielectric film 63 and the conductive film 62 for the floating gate are selectively etched to form the drain select transistor, the source select transistor and the gates of the memory cell transistors.

Thereafter, ions are implanted into the entire surface using the gate as an ion implant mask to form a source and drain junction 65. As such, the source select transistor SST and the drain select transistor DST, and the memory cell transistors MC1, . . . , MC16, which are connected in series between the source select transistor SST and the drain select transistor DST, are formed.

Referring to FIG. 6B, a photoresist PR is coated on the semiconductor substrate 60. The photoresist PR is patterned by exposure and development processed so that the source select transistor SST is exposed.

Thereafter, oxygen ions are implanted using the patterned photoresist PR as a mask.

At this time, oxygen is implanted with low energy so that it can be implanted into only the surface of the semiconductor substrate 60.

As a result, as shown in FIG. 6C, the oxide films 66 having a shallow depth are formed within the semiconductor substrate 60 at both sides of the gate 67 of the source select transistor SST. The depth of the oxide film 66 is shallower than that of the source and drain junctions 65 of the source select transistor SST.

If the device is formed as described above, the intensity of an electric field applied to the junction overlap region of the source select transistor SST can be reduced by the oxide films 66 even though there is a difference between the voltage of 0V applied to the gate of the source select transistor SST and the channel voltage (Vch).

Therefore, generation of hot carriers, which are the main cause of a Gate Induced Drain Current (GIDL), can be prohibited and a disturb characteristic can be improved accordingly.

Although the method and device described above may be applied to a flash memory device having six unit strings, the method and device may also be applied to a flash memory device more than 6 unit strings, including flash memory devices having 32 or more unit strings.

Using the method and device described above, the intensity of an electric field in the junction overlap region of the source select transistor adjacent to a non-selected memory cell transistor MC1 connected to the non-selected bit line of the selected W/L1 may be reduced. Therefore, generation of hot carriers can be reduced or prohibited and a program disturb characteristic may be improved. In particular, generation of hot carriers due to a high channel voltage of a non-selected memory cell transistor connected to a non-selected bit line and a selected word line can be prevented and because generation of a Gate Induced Drain Current (GIDL) due to hot carriers can be prevented, a program disturb characteristic can be improved.

Because the program disturb characteristic may be improved, the characteristics and reliability of devices may be improved.

In addition, including because the program disturb characteristic may be improved, the program speed of the flash memory device may be improved.

Further, the program disturb characteristic degradation phenomenon is less profound with devices becoming finer and higher integrated memory cells may be more easily fabricated.

Although certain examples of methods and apparatus constructed in accordance with the teachings of the invention have been described herein, the scope of coverage of this patent is not limited thereto. On the contrary, this patent covers all embodiments of the teachings of the invention fairly falling within the scope of the appended claims literally or under the doctrine of equivalents.

What is claimed is:

1. A NAND flash memory device, comprising:
a semiconductor substrate having a drain select transistor, a source select transistor, and memory cell transistors connected in series between the drain select transistor and the source select transistor; and
oxide films formed in the semiconductor substrate at each of a first side and a second side of a gate of the source select transistor.

2. The NAND flash memory device as claimed in claim 1, wherein the oxide films have a depth shallower than that of source and drain junctions of the source select transistor.

3. The NAND flash memory device as claimed in claim 1, wherein portions of the oxide films are respectively formed in source and drain junctions of the source select transistor.

4. A NAND flash memory device, comprising:
a semiconductor substrate having a drain select transistor, a source select transistor, and memory cell transistors connected in series between the drain select transistor and the source select transistor; and
oxide films formed in the semiconductor substrate at each of a first side and a second side of a gate of the source select transistor,
wherein the oxide films are separated from each other under the gate of the source select transistor.

5. The NAND flash memory device as claimed in claim 4, wherein the oxide films have a depth shallower than that of source and drain junctions of the source select transistor.

6. The NAND flash memory device as claimed in claim 4, wherein portions of the oxide films are respectively formed in source and drain junctions of the source select transistor.

7. A NAND flash memory device, comprising:
a semiconductor substrate having a drain select transistor, a source select transistor, and memory cell transistors connected in series between the drain select transistor and the source select transistor; and
oxide films formed in the semiconductor substrate at each of a first side and a second side of a gate of the source select transistor,
wherein the oxide films are located deeper than a tunnel oxide film of the source select transistor.

8. The NAND flash memory device as claimed in claim 7, wherein the oxide films have a depth shallower than that of source and drain junctions of the source select transistor.

9. The NAND flash memory device as claimed in claim 7, wherein portions of the oxide films are respectively formed in source and drain junctions of the source select transistor.
